(19) United States
(12) Patent Application Publication
(10) Pub. No.: US 2015/0298285 A1
(43) Pub. Date: Oct. 22, 2015

(54) MULTILAYER POLISHING PAD

(71) Applicant: TOYO TIRE & RUBBER CO., LTD., Osaka (JP)

(72) Inventor: Atsushi KAZUNO, Osaka (JP)

(73) Assignee: TOYO TIRE & RUBBER CO., LTD., Osaka-shi, Osaka (JP)

(21) Appl. No.: 14/440,989

(22) PCT Filed: Oct. 16, 2013
(86) PCT No.: PCT/JP2013/078092

§ 371 Date: May 6, 2015

(30) Foreign Application Priority Data
Nov. 8, 2012 (JP) 2012-246403

(51) Int. Cl. B24B 37/22; H01L 21/306

(52) U.S. Cl. CPC B24B 37/22; H01L 21/30625

(57) ABSTRACT

A multilayer polishing pad includes a cushion layer, an adhesive member, and a polishing layer placed on the cushion layer with the adhesive member interposed therebetween, wherein the adhesive member is an adhesive layer containing a polyester-based hot-melt adhesive or a double-sided tape including a base layer and the adhesive layer provided on each of both sides of the base layer, wherein the adhesive layer or the double-sided tape has a non-adhesive region that occupies 1 to 40% of the surface area, and the polyester-based hot-melt adhesive contains 100 parts by weight of a polyester resin as a base polymer and 2 to 10 parts by weight of an epoxy resin having two or more glycidyl groups per molecule.

### TECHNICAL FIELD

The present invention relates to a multilayer polishing pad by which the planarizing processing of optical materials such as lenses, reflecting mirrors and the like, silicon wafers, glass substrates for hard disks, aluminum substrates, and materials requiring a high degree of surface planarity such as those in general metal polishing processing can be carried out stably with high polishing efficiency. The multilayer polishing pad of the present invention is used particularly preferably in a process of planarizing a silicon wafer, and a device having an oxide layer, a metal layer or the like formed on a silicon wafer, before lamination and formation of the oxide layer, the metal layer or the like.

### BACKGROUND ART

Production of a semiconductor device involves a step of forming an electroconductive film on the surface of a wafer to form a wiring layer by photolithography, etching etc., a step of forming an interlaminar insulating film on the wiring layer, etc., and an uneven surface made of an electroconductive material such as metal and an insulating material is generated on the surface of a wafer by these steps. In recent years, processing for fine wiring and multilayer wiring is advancing for the purpose of higher integration of semiconductor integrated circuits, and accordingly techniques of planarizing an uneven surface of a wafer have become important.

As the method of planarizing an uneven surface of a wafer, a CMP method is generally used. CMP is a technique wherein while the surface of a wafer to be polished is pressed against a polishing surface of a polishing pad, the surface of the wafer is polished with slurry having abrasive grains dispersed therein. As shown in FIG. 1, a polishing apparatus used generally in CMP is provided for example with a polishing platen 2 for supporting a polishing pad 1, a supporting stand (polishing head) 5 for supporting a polished material (wafer) 4, a backing material for uniformly pressurizing a wafer, and a mechanism of feeding an abrasive. The polishing pad 1 is fitted with the polishing platen 2 for example via a double-sided tape. The polishing platen 2 and the supporting stand 5 are provided with rotating shafts 6 and 7 respectively and are arranged such that the polishing pad 1 and the polished material 4, both of which are supported by them, are opposed to each other. The supporting stand 5 is provided with a pressurizing mechanism for pushing the polished material 4 against the polishing pad 1.

Conventional polishing pads for use in high-precision polishing are generally produced using a polyurethane resin foam sheet. Unfortunately, such a polyurethane resin foam sheet has insufficient cushioning properties and therefore can hardly apply uniform pressure to the entire surface of a wafer, though it has high local-planarization performance. In general, therefore, a soft cushion layer is additionally provided on the back side of such a polyurethane resin foam sheet, and the resulting multilayer polishing pad is used for polishing.

For example, Patent Document 1 discloses that the polishing pad wherein a polishing region, a cushion layer and a transparent support film are laminated in this sequence, and a light transmission region is provided in an opening penetrating the polishing region and the cushion layer and on the transparent support film.

However, conventional multilayer polishing pads, which usually have a polishing layer and a cushion layer bonded together with a double-sided tape, have a problem in that a slurry can enter between the polishing layer and the cushion layer during polishing, so that the durability of the double-sided tape can decrease and delamination can easily occur between the polishing layer and the cushion layer.

Examples of proposed methods to solve this problem include the techniques described below.

Patent Document 2 discloses that a plastic film and a polishing pad are bonded together with a reactive hot-melt adhesive.

Patent Document 3 discloses a polishing pad including a base layer and a polishing layer bonded together with a hot-melt adhesive layer.

Patent Document 4 discloses a technique for forming a polishing pad including a polishing layer and a foundation layer bonded together with a double-sided tape, wherein a water blocking layer including a hot-melt adhesive is provided between the back side of the polishing layer and the double-sided tape to block a polishing slurry.

Patent Document 5 discloses a polishing pad for chemical-mechanical polishing comprising: a polishing layer, a bottom layer, wherein the bottom layer is substantially coextensive with the polishing layer, and a hot-melt adhesive, wherein the hot-melt adhesive joins together the polishing layer and the bottom layer, and the hot-melt adhesive comprises 2 to 18 wt % of EVA and is substantially resistant to delamination when the polishing layer attains a temperature of 40° C.

Unfortunately, the hot-melt adhesives disclosed in Patent Documents 2 to 5 have a problem in that their heat resistance is low, and at high temperature caused by polishing for a long period of time, their tackiness decreases so that delamination can easily occur between the polishing layer and the cushion layer or the like.

In order to solve the above problems, the present applicant has proposed a multilayer polishing pad having a long service life, which hardly undergoes peeling of a polishing layer from a cushion layer even in cases where the multilayer polishing pad is at high temperatures due to long-time polishing (unpublished).

However, when the long-time polishing was performed using the multilayer polishing pad, defects such as breakage may occur in the cushion layer.

### PRIOR ART DOCUMENTS

### Patent Documents

Patent Document 1: JP-A-2009-172727

Patent Document 2: JP-A-2002-224944

Patent Document 3: JP-A-2005-167200

Patent Document 4: JP-A-2009-95945

Patent Document 5: JP-A-2010-525956

### SUMMARY OF THE INVENTION

### Problems to be Solved by the Invention

An object of the present invention is to provide a multilayer polishing pad having a long service life, which hardly undergoes peeling of a polishing layer from a cushion layer even in cases where the multilayer polishing pad is at high temperatures due to long-time polishing and which does not cause no defect in the cushion layer even after long-time polishing. A further object of the invention is to provide a method for manufacturing a semiconductor device using such a multilayer polishing pad.

### Means for Solving the Problems

As a result of earnest investigations to solve the problems, the inventors have accomplished the invention based on the finding that the object can be achieved by the multilayer polishing pad shown below.

Specifically, the invention is directed to a multilayer polishing pad, comprising a cushion layer, an adhesive member, and a polishing layer placed on the cushion layer with the adhesive member interposed therebetween, wherein the adhesive member is an adhesive layer containing a polyester-based hot-melt adhesive or a double-sided tape comprising abase layer and the adhesive layer provided on each of both sides of the base layer, wherein the adhesive layer or the double-sided tape has a non-adhesive region that occupies 1 to 40% of a surface area of the adhesive layer or the double-sided tape, and the polyester-based hot-melt adhesive contains 100 parts by weight of a polyester resin as a base polymer and 2 to 10 parts by weight of an epoxy resin having two or more glycidyl groups per molecule.

The inventors have found that when the polyester resin of a polyester-based hot-melt adhesive used as a material to form an adhesive layer is crosslinked by addition of 2 to 10 parts by weight of an epoxy resin having two or more glycidyl groups per molecule based on 100 parts by weight of the polyester resin as a base polymer, it is possible to obtain a multilayer polishing pad that has higher adhesive-member durability against “shearing” during polishing and resists delamination between a polishing layer and a cushion layer even at high temperature caused by polishing for a long period of time.

If the added amount of the epoxy resin is less than 2 parts by weight, the adhesive member can have insufficient durability against “shearing,” which occurs during polishing when high temperature is produced by long-time polishing, so that delamination can easily occur between the polishing layer and the cushion layer. On the other hand, if it is more than 10 parts by weight, the adhesive layer can have too high hardness and thus lower tackiness, so that delamination can easily occur between the polishing layer and the cushion layer.

The hot-melt adhesive has very high adhesive strength. When the polishing layer and the cushion layer are stuck to each other with the hot-melt adhesive on the entire surfaces, the entire surface of one side of the cushion layer is firmly fixed by the hot-melt adhesive. As a result, deformation of the cushion layer for the “shearing” that occurs during polishing is limited and external force cannot be buffered, and therefore defects such as breakage are considered to occur in the cushion layer having low strength.

As in the present invention, the degree of fixation of the cushion layer to the adhesive layer or double-sided tape can be reduced by providing a non-adhesive region that occupies 1 to 40% of the surface area of the adhesive layer or double-sided tape. As a result, the cushion layer is easily deformed and external force is easily buffered, and therefore defects such as breakage are less likely to occur in the cushion layer. When the non-adhesive region is less than 1%, defects such as breakage may occur on the cushion layer due to the reasons described above. On the other hand, if the non-adhesive region is more than 40%, peeling of the polishing layer from the cushion layer easily occurs because the adhesive area becomes too small.

The polyester resin as a base polymer is preferably a crystalline polyester resin. When a crystalline polyester resin is used, the adhesive layer will have higher chemical resistance to a slurry and will be less likely to decrease in adhesive strength.

In the multilayer polishing pad of the invention, the polishing layer and the cushion layer may each have an opening, and the multilayer polishing pad of the invention may further include a transparent member placed in the opening of the polishing layer and bonded to the adhesive member.

The adhesive layer preferably has a thickness of 50 to 250 μm. If the adhesive layer has a thickness of less than 50 μm, the adhesive member may have insufficient durability against “shearing” during polishing when high temperature is produced by polishing for a long period of time, so that delamination may easily occur between the polishing layer and the cushion layer. Further, the melting efficiency under heating is improved and the hot-melt adhesive becomes easy to flow, and therefore the non-adhesive region easily disappears. If the adhesive layer has a thickness of more than 250 μm, transparency may decrease, so that the polishing pad may have degraded detection accuracy when it has a transparent member for use in optically detecting an end point. Moreover, the melting efficiency under heating is reduced and the adhesive strength tends to be reduced.

The polishing layer preferably has a surface with an arithmetic mean roughness (Ra) of 1 to 15 μm, more preferably 3 to 12 μm, on which the adhesive member is placed. When the surface roughness Ra is adjusted to 1 to 15 μm, a higher adhesive strength can be provided between the polishing layer and the adhesive member. If the Ra is less than 1 μm, it may be difficult to provide sufficiently high adhesive strength between the polishing layer and the adhesive member. If the Ra exceeds 15 μm, the adhesion between the polishing layer and the adhesive member may decrease, so that the adhesive strength between them may tend to decrease.

The multilayer polishing pad of the invention may include a polishing layer, an adhesive member, a cushion layer, and a double-sided adhesive sheet stacked in this order, and may further include a transparent member placed in a hole through the polishing layer, the adhesive member, and the cushion layer and placed on the double-sided adhesive sheet, wherein the adhesive member may be an adhesive layer containing a polyester-based hot-melt adhesive or may be a double-sided tape including a base layer and the adhesive layer provided on each of both sides of the base layer, wherein the adhesive layer or the double-sided tape has a non-adhesive region that occupies 1 to 40% of a surface area of the adhesive layer or the double-sided tape, and the polyester-based hot-melt adhesive contains 100 parts by weight of a polyester resin as a base polymer and 2 to 10 parts by weight of an epoxy resin having two or more glycidyl groups per molecule.

The invention is also directed to a method for manufacturing a multilayer polishing pad, including the steps of: stacking a polishing layer and a cushion layer with an adhesive member interposed therebetween to form a multilayer polishing sheet; forming a through hole in the multilayer polishing sheet; bonding a double-sided adhesive sheet to the cushion layer of the multilayer polishing sheet having the through hole; and placing a transparent member in the through hole and on the double-sided adhesive sheet, wherein the adhesive member is an adhesive layer containing a polyester-based hot-melt adhesive or a double-sided tape including a base layer and the adhesive layer provided on each of both sides of the base layer, wherein the adhesive layer or the double-sided tape has a non-adhesive region that occupies 1 to 40% of a surface area of the adhesive layer or the double-sided tape, and the polyester-based hot-melt adhesive contains 100 parts by weight of a polyester resin as a base polymer and 2 to 10 parts by weight of an epoxy resin having two or more glycidyl groups per molecule.

Also, the invention relates to a method for manufacturing a semiconductor device, comprising a step of polishing a surface of a semiconductor wafer using the aforementioned multilayer polishing pad.

### Effect of the Invention

The multilayer polishing pad of the invention resists delamination between the polishing layer and the cushion layer even at high temperature caused by polishing for a long period of time because the adhesive member interposed between the polishing layer and the cushion layer stacked together contains the specified polyester-based hot-melt adhesive. Also in the multilayer polishing pad of the present invention, the polishing layer and the cushion layer are stuck to each other using an adhesive layer or double-sided tape having a non-adhesive region that occupies 1 to 40% of the surface area, and therefore defects such as breakage do not occur in the cushion layer even if a long-time polishing is performed.

### BRIEF DESCRIPTION OF THE DRAWINGS

FIG. 1 is a schematic diagram showing an example of a polishing apparatus used in CMP.

FIG. 2 is a schematic cross-sectional view showing an example of the multilayer polishing pad of the invention.

FIG. 3 is a schematic cross-sectional view showing another example of the multilayer polishing pad of the invention.

### MODE FOR CARRYING OUT THE INVENTION

In the invention, the polishing layer is not restricted as long as it is a foam containing fine cells. For example, the material for the foam may be one of or a blend of two or more of polyurethane resin, polyester resin, polyamide resin, acrylic resin, polycarbonate resin, halogen-containing resin (such as polyvinyl chloride, polytetrafluoroethylene and polyvinylidene fluoride etc.), polystyrene, olefin resin (such as polyethylene and polypropylene etc.), epoxy resin, and photosensitive resin. Polyurethane resin is particularly preferred as a material for forming the polishing layer because polyurethane resin has good wear resistance and because urethane polymers having desired physical properties can be easily obtained through changing the composition of raw materials in various manners. Hereinafter, polyurethane resin will be described as a typical example of the material for the foam.

The polyurethane resin contains an isocyanate component, a polyol component (high-molecular-weight polyol, low-molecular-weight polyol etc.) and a chain extender.

As the isocyanate component, a compound known in the field of polyurethane can be used without particular limitation. The isocyanate component includes, for example, aromatic diisocyanates such as 2,4-toluene diisocyanate, 2,6-toluene diisocyanate, 2,2′-diphenyl methane diisocyanate, 2,4′-diphenyl methane diisocyanate, 4,4′-diphenyl methane diisocyanate, 1,5-naphthalene diisocyanate, p-phenylene diisocyanate, m-phenylene diisocyanate, p-xylylene diisocyanate and m-xylylene diisocyanate, aliphatic diisocyanates such as ethylene diisocyanate, 2,2,4-trimethyl hexamethylene diisocyanate and 1,6-hexamethylene diisocyanate, and cycloaliphatic diisocyanates such as 1,4-cyclohexane diisocyanate, 4,4′-dicyclohexyl methane diisocyanate, isophorone diisocyanate and norbornane diisocyanate. These may be used alone or as a mixture of two or more thereof.

As the high-molecular-weight polyol, a compound known in the field of polyurethane can be used without particular limitation. The high-molecular-weight polyol includes, for example, polyether polyols represented by polytetramethylene ether glycol and polyethylene glycol, polyester polyols represented by polybutylene adipate, polyester polycarbonate polyols exemplified by reaction products of polyester glycols such as polycaprolactone polyol and polycaprolactone with alkylene carbonate, polyester polycarbonate polyols obtained by reacting ethylene carbonate with a multivalent alcohol and reacting the resulting reaction mixture with an organic dicarboxylic acid, and polycarbonate polyols obtained by ester exchange reaction of a polyhydroxyl compound with aryl carbonate. These may be used singly or as a mixture of two or more thereof.

Besides the above high-molecular-weight polyol described in the above as a polyol component, it is preferred to concomitantly use a low-molecular-weight polyol such as ethyleneglycol, 1,2-propylene glycol, 1,3-propylene glycol, 1,2-butanediol, 1,3-butanediol, 1,4-butanediol, 2,3-butanediol, 1,6-hexanediol, neopentylglyol, 1,4-cyclohexanedimethanol, 3-methyl-1,5-pentanediol, diethyleneglycol, triethyleneglycol, 1,4-bis(2-hydroxyethoxy)benzene, trimethylolpropane, glycerin, 1,2,6-hexanetriol, pentaerythritol, tetramethylol cyclohexane, methylglucoside, sorbitol, mannitol, dulcitol, sucrose, 2,2,6,6-tetrakis(hydroxymethyl)cyclohexanol, diethanolamine, N-methyldiethanolamine and triethanol amine. Low-molecular-weight polyamine such as ethylenediamine, tolylenediamine, diphenylmethanediamine, and diethylenetriamine may be used. Alcohol amine such as monoethanol amine, 2-(2-aminoethylamino) ethanol and monopropanol amine may be used. These may be used singly or in combination of two or more kinds. The content of the low-molecular-weight polyol, the low-molecular-weight polyamine, or other materials is not particularly limited, and may be appropriately determined depending on the properties required of the polishing pad (polishing layer) to be manufactured.

In the case where a polyurethane resin foam is produced by means of a prepolymer method, a chain extender is used in curing of a prepolymer. A chain extender is an organic compound having at least two active hydrogen groups and examples of the active hydrogen group include: a hydroxyl group, a primary or secondary amino group, a thiol group (SH) and the like. Concrete examples of the chain extender include: polyamines such as 4,4′-methylenebis(o-chloroaniline)(MOCA), 2,6-dichloro-p-phenylenediamine, 4,4′-methylenebis(2,3-dichloroaniline), 3,5-bis(methylthio) -2, 4-toluenediamine, 3,5-bis(methylthio) -2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 4,4′-diamino-3,3′, 5,5′-tetraethyldiphenylmethane, 4,4′-diamino-3,3′-diisopropyl-5,5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminophenylmethane, 3,3′-diethyl-4,4′-diaminodiphenylmethane, m-xylylenediamine, N,N′-di-sec-butyl-p-phenylenediamine, m-phenylenediamine and p-xylylenediamine; the low-moleculer-weight polyol; and the low-molecular-weight polyamine. The chain extenders described above may be used either alone or in mixture of two kinds or more.

A ratio between an isocyanate component, a polyol component and a chain extender in the invention can be altered in various ways according to molecular weights thereof, desired physical properties of a polishing pad and the like. In order to obtain a polishing pad with desired polishing characteristics, a ratio of the number of isocyanate groups in an isocyanate component relative to a total number of active hydrogen groups (hydroxyl groups+amino groups) in a polyol component and a chain extender is preferably in the range of from 0.80 to 1.20 and more preferably in the range of from 0.99 to 1.15. When the number of isocyanate groups is outside the aforementioned range, there is a tendency that curing deficiency is caused, required specific gravity and hardness are not obtained, and polishing property is deteriorated.

A polyurethane resin foam can be produced by applying a melting method, a solution method or a known polymerization technique, among which preferable is a melting method, consideration being given to a cost, a working environment and the like.

Manufacture of a polyurethane resin foam is enabled by means of either a prepolymer method or a one shot method, of which preferable is a prepolymer method in which an isocyanate-terminated prepolymer is synthesized from an isocyanate component and a polyol component in advance, with which a chain extender is reacted since physical properties of an obtained polyurethane resin is excellent.

Manufacturing methods of a polyurethane resin foam include: a method in which hollow beads are added, a mechanical foaming method, a chemical foaming method and the like.

Particularly, preferred is a mechanical foaming method using a silicone-based surfactant which is a copolymer of polyalkylsiloxane and polyether and has no an active hydrogen group.

A stabilizer such as antioxidant, a lubricant, a pigment, a filler, an antistatic agent and other additives maybe added, as needed.

The polyurethane resin foam may be of a closed cell type or an open cell type.

Production of the polyurethane resin foam may be in a batch system where each component is weighed out, introduced into a vessel and mixed or in a continuous production system where each component and a non-reactive gas are continuously supplied to, and stirred in, a stirring apparatus and the resulting forming reaction liquid is transferred to produce molded articles.

A manufacturing method of a polyurethane resin foam may be performed in ways: in one of which a prepolymer which is a raw material from which a polyurethane foam is made is put into a reactor, thereafter a chain extender is mixed into the prepolymer, the mixture is agitated, thereafter the mixture is cast into a mold with a predetermined size to thereby prepare a block and the block is sliced with a slicer like a planer or a band saw; and in another of which in the step of casting into the mold, a thin sheet may be directly produced. Besides, a still another way may be adopted in which a resin of raw material is melted, the melt is extruded through a T die to thereby mold a polyurethane resin foam directly in the shape of a sheet.

An average cell diameter of a polyurethane resin foam is preferably in the range of from 30 to 80 μm and more preferably in the range of from 30 to 60 μm. If an average cell diameter falls outside the range, a tendency arises that a polishing rate is decreased and a planarity of an object to be polished (a wafer) after polishing is reduced.

Preferably, the polyurethane resin foam has a specific gravity ranging from 0.5 to 1.3. When the specific gravity is less than 0.5, the surface strength of the polishing layer decreases, so that the planarity of the object to be polished tends to decrease. When the specific gravity is larger than 1.3, the cell number on the surface of the polishing layer decreases, so that the polishing rate tends to decrease despite excellent planarity.

Preferably, the polyurethane resin foam has a hardness measured by ASKER D hardness meter, ranging from 40 to 75 degrees. When the ASKER D hardness is less than 40 degrees, the planarity of the object to be polished decreases, while when the hardness is more than 75 degrees, the uniformity of the object to be polished tends to decrease despite excellent planarity.

Preferably, a polishing surface of the polishing layer, which comes into contact with an object to be polished have a asperity structure provided for retaining and refreshing a slurry. A polishing layer made of a foam has a number of openings in the polishing surface, and has a function of retaining and refreshing a slurry. By forming an asperity structure on the polishing surface, it is possible to conduct retention and refreshment of the slurry more efficiently, and to prevent the object to be polished from breaking due to adsorption of the material to be polished. The shape of the asperity structure is not particularly limited insofar as it is able to retain and refresh a slurry, and for example, XY grating groove, concentric ring groove, through-hole, non-through-hole, polygonal column, circular cylinder, spiral groove, eccentric ring groove, radial groove, and combination thereof can be recited. These asperity structures generally have regularity, however, groove pitch, groove width, groove depth and the like maybe varied by a certain range for achieving desired retention and refreshment of slurry.

The polishing layer may have any shape such as a circular shape or an elongated shape. The size of the polishing layer may be appropriately adjusted depending on the polishing apparatus to be used. When the polishing layer is circular, it may have a diameter of about 30 to about 150 cm, and when the polishing layer has an elongated shape, it may have a length of about 5 to about 15 m and a width of about 60 to about 250 cm.

The thickness of the polishing layer is generally, but is not limited to, about 0.8 to 4 mm, and preferably 1.2 to 2.5 mm.

The multilayer polishing pad of the invention is made by bonding the polishing layer and the cushion layer together with the adhesive member.

The cushion layer is a layer having an elastic modulus lower than that of the polishing layer. The cushion layer is necessary for CMP to achieve both good planarity and good uniformity, which are usually in a trade-off relationship. The term “planarity” refers to the flatness of a patterned part formed by polishing an object to be polished having fine irregularities, which are produced in a patterning process. The term “uniformity” refers to the entire uniformity of an object to be polished. The characteristics of the polishing layer contribute to an improvement in planarity, and the characteristics of the cushion layer contribute to an improvement in uniformity.

Examples of the cushion layer include nonwoven fiber fabrics such as polyester nonwoven fabrics, nylon nonwoven fabrics, and acrylic nonwoven fabrics; resin impregnated nonwoven fabrics such as polyurethane impregnated polyester nonwoven fabrics; polymeric resin foams such as polyurethane foams and polyethylene foams; rubber resins such butadiene rubber and isoprene rubber; and photosensitive resins, etc.

The thickness of the cushion layer is preferably, but not limited to, 300 to 1,800 μm, more preferably 700 to 1,400 μm.

A resin film having a rate of dimensional change of 1.2% or less between before and after it is heated at 150° C. for 30 minutes is preferably provided on one side of the cushion layer (on the polishing platen side). The resin film more preferably has a rate of dimensional change of 0.8% or less, even more preferably 0.4% or less. By providing the resin film, it is possible to suppress warp of the multilayer polishing pad. Examples of the resin film having such properties include a polyethylene terephthalate film, a polyethylene naphthalate film, and a polyimide film each having undergone thermal shrinkage treatment.

The thickness of the resin film is preferably, but not limited to, 10 to 200 μm, more preferably 15 to 55 μm, in view of stiffness, dimensional stability during heating, and other properties.

The adhesive member to be used is an adhesive layer containing a polyester-based hot-melt adhesive or a double-sided tape including a base layer and such an adhesive layer provided on each of both sides of the base layer.

The polyester-based hot-melt adhesive contains at least a polyester resin as a base polymer and an epoxy resin having two or more glycidyl groups per molecule, in which the epoxy resin is a crosslinking component.

The polyester resin may be any known polyester resin which is obtained by condensation polymerization of an acid and a polyol or other polymerization processes. In particular, the polyester resin is preferably a crystalline polyester resin.

Examples of the acid include aromatic dicarboxylic acids, aliphatic dicarboxylic acids, and alicyclic dicarboxylic acids, etc. These maybe used alone or in combination of two or more.

Examples of aromatic dicarboxylic acids include terephthalic acid, isophthalic acid, phthalic anhydride, α-naphthalene dicarboxylic acid, β-naphthalene dicarboxylic acid, and their ester forms, etc.

Examples of aliphatic dicarboxylic acids include succinic acid, glutaric acid, adipic acid, pimelic acid, suberic acid, azelaic acid, sebacic acid, undecylenic acid, dodecanedioic acid, and their ester forms, etc.

Examples of alicyclic dicarboxylic acids include 1,4-cyclohexane dicarboxylic acid, tetrahydrophthalic anhydride, hexahydrophthalic anhydride, etc.

An unsaturated acid such as maleic acid, fumaric acid, or dimer acid, a polycarboxylic acid such as trimellitic acid or pyromellitic acid, or other acids may also be used as the acid in combination with any of the above acids.

Examples of the polyol include dihydric alcohols such as aliphatic glycols and alicyclic glycols, and polyhydric alcohols. These may be used alone or in combination of two or more.

Examples of aliphatic glycols include ethylene glycol, 1,2-propylene glycol, 1,3-propylene glycol, 1,3-butanediol, 1,4-butanediol, 1,5-pentanediol, 1,6-hexanediol, 1,8-octanediol, 1,9-nonanediol, neopentyl glycol, 3-methylpentanediol, 2,2,3-trimethylpentanediol, diethylene glycol, triethylene glycol, dipropylene glycol, etc.

Examples of alicyclic glycols include 1,4-cyclohexanedimethanol, hydrogenated bisphenol A, etc.

Examples of polyhydric alcohols include glycerin, trimethylolethane, trimethylolpropane, pentaerythritol, etc.

The crystalline polyester resin can be synthesized by known methods. Examples include melt polymerization methods including adding raw materials and a catalyst and heating the mixture at a temperature equal to or higher than the melting point of the desired product, solid-phase polymerization methods including performing polymerization at a temperature equal to or lower than the melting point of the desired product, and solution polymerization methods using a solvent, etc. Any of these methods may be used.

The crystalline polyester resin preferably has a melting point of 100 to 200° C. If the melting point is lower than 100° C., the adhesive strength of the hot-melt adhesive can be lowered by heat generated during polishing. If the melting point is higher than 200° C., a higher temperature will be needed to melt the hot-melt adhesive, which may warp the multilayer polishing pad and tend to have an adverse effect on the polishing characteristics.

The crystalline polyester resin preferably has a number average molecular weight of 5,000 to 50,000. If the number average molecular weight is less than 5,000, the hot-melt adhesive may have lower mechanical characteristics, so that a sufficient level of tackiness and durability may fail to be obtained. If the number average molecular weight is more than 50,000, a production failure such as gelation may occur in the process of synthesizing the crystalline polyester resin, or the hot-melt adhesive may tend to have lower performance.

Examples of the epoxy resin include aromatic epoxy resins such as bisphenol A type epoxy resins, brominated bisphenol A type epoxy resins, bisphenol F type epoxy resins, bisphenol AD type epoxy resins, stilbene type epoxy resins, biphenyl type epoxy resins, bisphenol A novolac type epoxy resins, cresol novolac type epoxy resins, diaminodiphenylmethane type epoxy resins, and polyphenyl-based epoxy resins such as tetrakis (hydroxyphenyl) ethane-based epoxy resins, fluorene-containing epoxy resins, and epoxy resins containing a triglycidyl isocyanurate moiety or a heteroaromatic ring (such as a triazine ring); and non-aromatic epoxy resins such as aliphatic glycidyl ether type epoxy resins, aliphatic glycidyl ester type epoxy resins, alicyclic glycidyl ether type epoxy resins, and alicyclic glycidyl ester type epoxy resins. These may be used alone or in combination of two or more.

Among them, cresol novolac type epoxy resins are preferably used in view of tackiness to the polishing layer during polishing.

The epoxy resin is necessarily added in an amount of 2 to 10 parts by weight, preferably in an amount of 3 to 7 parts by weight, to 100 parts by weight of the polyester resin as a base polymer.

The polyester-based hot-melt adhesive may also contain known additives such as a softener such as an olefin resin, a tackifier, a filler, a stabilizer, and a coupling agent. The adhesive may also contain a known inorganic filler such as talc and other materials.

The polyester-based hot-melt adhesive can be prepared by mixing at least the polyester resin and the epoxy resin and optional materials by any method. For example, the polyester-based hot-melt adhesive can be prepared by mixing the respective raw materials using an extruder such as a mono-screw extruder, a co-rotating intermeshing parallel twin screw extruder, a counter-rotating intermeshing parallel twin screw extruder, a counter-rotating intermeshing inclined twin screw extruder, a non-intermeshing twin screw extruder, an incompletely intermeshing twin screw extruder, a co-kneader extruder, a planetary gear extruder, a transfer mixing extruder, a ram extruder, or a roller extruder, or a kneader, etc.

The polyester-based hot-melt adhesive preferably has a melting point of 100 to 200° C.

The polyester-based hot-melt adhesive preferably has a specific gravity of 1.1 to 1.3.

The polyester-based hot-melt adhesive preferably has a melt flow index of 16 to 26 g/10 minutes under the conditions of 150° C. and a load of 2.16 kg.

The polyester-based hot-melt adhesive maybe used in any form, such as in the form of a pellet, a powder, a sheet, a film, or a solvent solution. In the invention, however, the polyester-based hot-melt adhesive is preferably used in the form of a sheet or a film.

The polishing layer and the cushion layer may be bonded together by any method. For example, the polishing layer and the cushion layer may be bonded together by a method including using the polyester-based hot-melt adhesive to form an adhesive layer on the cushion layer, melting the adhesive layer by heat from a heater, and then press-laminating the polishing layer onto the molten adhesive layer.

The adhesive layer has a non-adhesive region that occupies 1 to 40% of the surface area. The non-adhesive region preferably occupies 3 to 20% of the surface area.

Examples of the shape of the non-adhesive region include, but are not particularly limited to, a circular shape and a polygonal shape. In the case of a circular shape, the diameter is about 1 to 10 mm. The non-adhesive region is preferably formed uniformly on the surface of the adhesive layer.

A method for forming the non-adhesive region is not particularly limited, but a method of punching a sheet-like or film-like adhesive layer in a specific shape and pattern is preferable from the viewpoint of working efficiency.

The adhesive layer preferably has a thickness of 50 to 250 μm, more preferably 75 to 125 μm.

A double-sided tape including a base layer and the adhesive layers provided on both sides of the base layer may also be used instead of the adhesive layer. The adhesive layer has a non-adhesive region that occupies 1 to 40% of the surface area as mentioned above. The base layer can prevent a slurry from permeating to the cushion layer side, so that delamination between the cushion layer and the adhesive layer can be prevented.

The base layer may be a resin film or the like. Examples of the resin film include polyester films such as polyethylene terephthalate films and polyethylene naphthalate films; polyolefin films such as polyethylene films and polypropylene films; nylon films; and polyimide films, etc. Among them, polyester films are preferably used, which have high ability to prevent water permeation.

The base layer to be used is preferably a resin film having a rate of dimensional change of 1.2% or less between before and after it is heated at 150° C. for 30 minutes. The resin film more preferably has a rate of dimensional change of 0.8% or less, even more preferably 0.4% or less. By using the resin film, it is possible to suppress warp of the multilayer polishing pad. Examples of the resin film having such properties include a polyethylene terephthalate film, a polyethylene naphthalate film, and a polyimide film each having undergone thermal shrinkage treatment.

The surface of the base layer may be subjected to an adhesion-facilitating treatment such as a corona treatment or a plasma treatment.

The thickness of the base layer is preferably, but not limited to, 10 to 200 μm, more preferably 15 to 55 μm, in view of transparency, flexibility, stiffness, dimensional stability during heating, and other properties.

When the double-sided tape is used, the thickness of the adhesive layer is preferably from 50 to 250 μm, more preferably from 75 to 125 μm.

The multilayer polishing pad of the invention may also be provided with a double-sided tape on its side to be attached to a platen.

FIG. 2 is a schematic cross-sectional view showing an example of the multilayer polishing pad of the invention. A polishing layer 8 is provided with a transparent member 9 for use in optically detecting an endpoint during polishing. The transparent member 9 is fixed by being fit in an opening 10 formed in the polishing layer 8 and being bonded to an adhesive member 11 under the polishing layer 8. When the transparent member 9 is placed in the polishing layer 8, an opening 13 for transmitting light is preferably formed in the cushion layer 12.

The adhesive member 11 of the invention has the function of preventing a slurry from leaking to the cushion layer 12 side (water-blocking function) when the slurry enters between the polishing layer 8 and the transparent member 9. In addition, when the slurry enters between the polishing layer 8 and the transparent member 9, the adhesive strength of the adhesive member 11 of the invention will not reduced by the slurry, and thus the adhesive member 11 of the invention can effectively prevent delamination between the polishing layer 8 and the cushion layer 12.

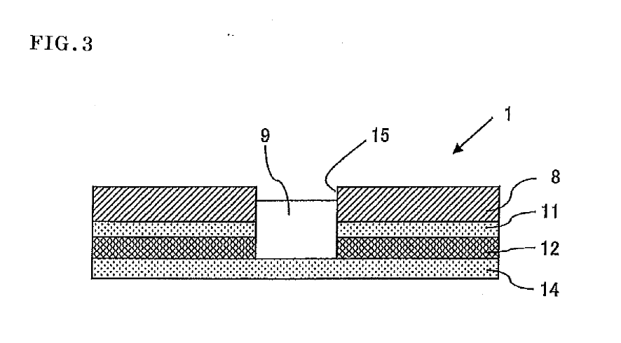

FIG. 3 is a schematic cross-sectional view showing another example of the multilayer polishing pad of the invention. The multilayer polishing pad 1 includes a polishing layer 8, an adhesive member 11, a cushion layer 12, and a double-sided adhesive sheet 14, which are stacked in this order, and further includes a transparent member 9 that is provided on the double-sided adhesive sheet 14 and inserted in a through hole 15 formed through the polishing layer 8, the adhesive member 11, and the cushion layer 12.

The double-sided adhesive sheet 14 is generally what is called a double-sided tape, which includes a base layer and adhesive layers provided on both sides of the base layer. The double-sided adhesive sheet 14 is used to bond the multilayer polishing pad 1 to a polishing platen 2.

For example, the multilayer polishing pad 1 can be manufactured by the following process. First, the polishing layer 8 and the cushion layer 12 are stacked with the adhesive member 11 interposed therebetween to form a multilayer polishing sheet. The through hole 15 is formed in the resulting multilayer polishing sheet. The double-sided adhesive sheet 14 is bonded to the cushion layer 12 of the multilayer polishing sheet having the through hole 15. Subsequently, the transparent member 9 is inserted into the through hole 15 and placed on the double-sided adhesive sheet 14. Alternatively, the double-sided adhesive sheet 14 may be bonded to the cushion layer 12 and the transparent member 9 after the transparent member 9 is inserted into the through hole 15.

The surface level of the transparent member 9 is preferably equal to that of the polishing layer 8 or preferably lower than that of the polishing layer 8. If the surface level of the transparent member 9 is higher than that of the polishing layer 8, the projection part may scratch the material being polished. In addition, the transparent member 9 may be deformed by stress applied during polishing, so that large optical distortion may occur and reduce the accuracy of the optical detection of a polishing end point.

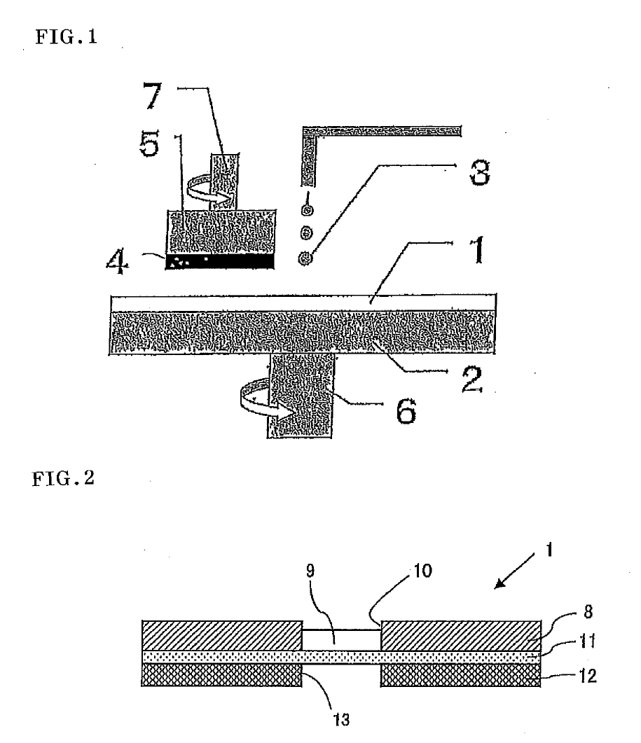

A semiconductor device is fabricated after operation in a step of polishing a surface of a semiconductor wafer with a multilayer polishing pad. The term, a semiconductor wafer, generally means a silicon wafer on which a wiring metal and an oxide layer are stacked. No specific limitation is imposed on a polishing method of a semiconductor wafer or a polishing apparatus, and polishing is performed with a polishing apparatus equipped, as shown in FIG. 1, with a polishing platen 2 supporting a multilayer polishing pad 1, a polishing head 5 holding a semiconductor wafer 4, a backing material for applying a uniform pressure against the wafer and a supply mechanism of a polishing agent 3. The multilayer polishing pad 1 is mounted on the polishing platen 2 by adhering the pad to the platen with a double-sided adhesive tape. The polishing platen 2 and the polishing head 5 are disposed so that the multilayer polishing pad 1 and the semiconductor wafer 4 supported or held by them oppositely face each other and provided with respective rotary shafts 6 and 7. A pressure mechanism for pressing the semiconductor wafer 4 to the multilayer polishing pad 1 is installed on the polishing head 5 side. During polishing, the semiconductor wafer 4 is polished by being pressed against the multilayer polishing pad 1 while the polishing platen 2 and the polishing head 5 are rotated and a slurry is fed. No specific limitation is placed on a flow rate of the slurry, a polishing load, a polishing platen rotation number and a wafer rotation number, which are properly adjusted.

Protrusions on the surface of the semiconductor wafer 4 are thereby removed and polished flatly. Thereafter, a semiconductor device is produced therefrom through dicing, bonding, packaging etc. The semiconductor device is used in an arithmetic processor, a memory etc.

### EXAMPLES

Description will be given of the invention with examples, while the invention is not limited to description in the examples.

[Methods for Measurement and Evaluation]

(Measurement of Number Average Molecular Weight)

The number average molecular weight was measured as a polystyrene-equivalent value by GPC (gel permeation chromatography) with standard polystyrene. GPC system: LC-10A manufactured by Shimadzu Corporation Columns: three columns PLgel (5 μm, 500 Å), PLgel (5 μm, 100 Å) and PLgel (5 μm, 50 Å) each manufactured by Polymer Laboratories were coupled and used.
Flow rate: 1.0 ml/minute
Concentration: 1.0 g/l
Injection volume: 40 μl
Column temperature: 40° C.
Eluent: tetrahydrofuran

(Measurement of Melting Point)

The melting point of the polyester-based hot-melt adhesive was measured at a rate of temperature rise of 20° C./minute using TOLEDO DSC822 (manufactured by Mettler-Toledo International Inc.).

(Measurement of Specific Gravity)

The measurement was performed according to JIS Z 8807-1976. A 4 cm×8.5 cm adhesive layer strip (of arbitrary thickness) was cut from the polyester-based hot-melt adhesive and used as a sample for the specific gravity measurement. The sample was allowed to stand in an environment at a temperature of 23° C.±2° C. and a humidity of 50%±5% for 16 hours. The sample was measured for specific gravity using a specific gravity meter (manufactured by Sartorius AG).

(Measurement of Melt Flow Index (MI))

The melt flow index of the polyester-based hot-melt adhesive was measured according to ASTM-D-1238 under the conditions of 150° C. and 2.16 kg.

(Evaluation of Peeling State)

Three sample pieces each having a size of 25 mm×25 mm were cut from the prepared multilayer polishing pad, and in a thermostatic chamber adjusted to 80° C., the polishing layer and the cushion layer of each sample were pulled from each other at a pulling rate of 300 mm/minute. Then, the peeling state of the layers of the sample was confirmed.

(State Evaluation of Polishing Pad after Polishing)

With use of a prepared multilayer polishing pad and a polishing apparatus ARW-8C1A (manufactured by MAT Corporation), wafers each having an 8-inch silicon wafer, a titanium nitride film formed in a thickness of 400 angstroms on an 8-inch silicon wafer and a tungsten film formed thereon in a thickness of 8000 angstroms were polished for 5 minutes per wafer, followed by 24 hour continuous polishing while replacing the wafer. Then, the state of the polishing pad was evaluated. It should be noted that after polishing the tungsten film by polishing each wafer for 5 minutes, the titanium nitride film having a high level of polishing friction was polished to thereby increase loads (shear force due to friction and temperature due to friction) on the multilayer polishing pad.

The polishing conditions were as follows. W2000 (manufactured by Cabot Corporation) was diluted twice with ultrapure water. Two percent by weight of aqueous hydrogen peroxide was added to the resulting dilution. The resulting slurry was added at a flow rate of 150 ml/minute during the polishing, in which the polishing load, the retainer load, the number of polishing platen revolutions, and the number of wafer revolutions were 5 psi, 6 psi, 100 rpm, and 100 rpm, respectively. Using a dresser (DK45, manufactured by Saesol), the surface of the polishing pad was dressed at a dresser rotation rate of 60 rpm for polishing.

### Example 1

(Preparation of Polishing Layer)

To a vessel were added 1,229 parts by weight of toluene diisocyanate (a mixture of 2,4-diisocyanate/2,6-diisocyanate=80/20), 272 parts by weight of 4,4′-dicyclohexylmethane diisocyanate, 1,901 parts by weight of polytetramethylene ether glycol with a number average molecular weight of 1,018, and 198 parts by weight of diethylene glycol, and allowed to react at 70° C. for 4 hours, so that an isocyanate-terminated prepolymer was obtained.

To a polymerization vessel were added 100 parts by weight of the prepolymer and 3 parts by weight of a silicone surfactant (SH-192 manufactured by Dow Corning Toray Co., Ltd.) and mixed. The mixture was adjusted to 80° C. and degassed under reduced pressure. Subsequently, the reaction system was vigorously stirred for about 4 minutes with a stirring blade at a rotational speed of 900 rpm so that air bubbles were incorporated into the reaction system. Thereto was added 26 parts by weight of MOCA (CUAMINE-MT, manufactured by IHARA CHEMICAL INDUSTRY CO., LTD.), whose temperature was adjusted to 120° C. in advance. The liquid mixture was stirred for about 1 minute and then poured into a pan-shaped open mold (casting vessel). At the point when the liquid mixture lost its fluidity, it was placed in an oven, and subjected to post curing at 100° C. for 16 hours, so that a polyurethane resin foam block was obtained.

While heated at about 80° C., the polyurethane resin foam block was sliced using a slicer (VGW-125 manufactured by AMITEC Corporation), so that a polyurethane resin foam sheet (50 μm in average cell diameter, 0.86 in specific gravity, and 52 degrees in hardness) was obtained. In a buffing machine (manufactured by AMITEC Corporation), the surface of the sheet was then buffed subsequently using #120, #240, and #400 sandpaper, until its thickness reached 2 mm, so that a sheet with regulated thickness accuracy was obtained. The non-polished surface of the sheet had an arithmetic average roughness (Ra) of 5 μm. It should be noted that the arithmetic average roughness (Ra) of the non-polished surface was measured in accordance with JIS B0601-1994. The buffed sheet was stamped into a piece with a diameter of 61 cm. Concentric circular grooves with a width 0.25 mm, a pitch of 1.5 mm, and a depth of 0.6 mm were formed on the surface of the piece using a grooving machine (manufactured by Techno Corporation), so that a polishing layer was obtained.

(Preparation of Multilayer Polishing Pad)

Circular holes arranged in a square lattice shape (1.6 mm in diameter×5.5 mm in pitch) were formed on an adhesive layer (100 μm in thickness) including a polyester-based hot-melt adhesive containing 100 parts by weight of a crystalline polyester resin (VYLON GM420 manufactured by Toyobo Co., Ltd.) and 5 parts by weight of an o-cresol novolac type epoxy resin (EOCN 4400 manufactured by Nippon Kayaku Co., Ltd.) having two or more glycidyl groups per molecule. The adhesive layer was laminated on a cushion layer made of foamed urethane (NIPPALAY EXT manufactured by NHK Spring Co., Ltd.) and the surface of the adhesive layer was heated to 150° C. using an infrared heater, so that the adhesive layer was melted. Subsequently, using a laminator, the prepared polishing layer was laminated and pressure-bonded onto the molten adhesive layer, and the resulting laminate was cut into the size of the polishing layer. Using a laminator, a double-sided pressure-sensitive adhesive tape (442JA manufactured by 3M Company) was further bonded to the other side of the cushion layer, so that a multilayer polishing pad was obtained. The polyester-based hot-melt adhesive had a melting point of 142° C., a specific gravity of 1.22, and a melt flow index of 21 g/10 minutes.

### Example 2

A multilayer polishing pad was prepared in the same manner as in Example 1, except that circular holes (1.6 mm in diameter×10 mm in pitch) were formed in a square lattice shape on the adhesive layer.

### Example 3

A multilayer polishing pad was prepared in the same manner as in Example 1, except that circular holes (8 mm in diameter×12 mm in pitch) were formed in a square lattice shape on the adhesive layer.

### Example 4

A multilayer polishing pad was prepared in the same manner as in Example 1, except that circular holes (5 mm in diameter×5 mm in pitch) were formed in a square lattice shape on the adhesive layer.

### Example 5

A multilayer polishing pad was prepared in the same manner as in Example 1, except that circular holes (8 mm in diameter×7 mm in pitch) were formed in a square lattice shape on the adhesive layer.

### Example 6

A multilayer polishing pad was prepared in the same manner as in Example 1, except that circular holes (8 mm in diameter×4 mm in pitch) were formed in a square lattice shape on the adhesive layer.

### Comparative Example 1

A multilayer polishing pad was prepared in the same manner as in Example 1, except that circular holes (10 mm in diameter×3 mm in pitch) were formed in a square lattice shape on the adhesive layer.

### Comparative Example 2

A multilayer polishing pad was prepared in the same manner as in Example 1, except that circular holes (0.5 mm in diameter×9.5 mm in pitch) were formed in a square lattice shape on the adhesive layer.

### Example 7

A multilayer polishing pad was prepared using the same process as in Example 1, except that a polyester-based hot-melt adhesive containing 100 parts by weight of a crystalline polyester resin (VYLON GM420 manufactured by TOYOBO CO., LTD.) and 2 parts by weight of an o-cresol novolac type epoxy resin (EOCN 4400 manufactured by Nippon Kayaku Co., Ltd.) having at least two glycidyl groups per molecule was used instead. The polyester-based hot-melt adhesive had a melting point of 140° C., a specific gravity of 1.24, and a melt flow index of 26 g/10 minutes.

### Example 8

A multilayer polishing pad was prepared using the same process as in Example 1, except that a polyester-based hot-melt adhesive containing 100 parts by weight of a crystalline polyester resin (VYLON GM420 manufactured by TOYOBO CO., LTD.) and 10 parts by weight of an o-cresol novolac type epoxy resin (EOCN 4400 manufactured by Nippon Kayaku Co., Ltd.) having at least two glycidyl groups per molecule was used instead. The polyester-based hot-melt adhesive had a melting point of 145° C., a specific gravity of 1.19, and a melt flow index of 16 g/10 minutes.

### Comparative Example 3

A multilayer polishing pad was prepared using the same process as in Example 1, except that a polyester-based hot-melt adhesive containing 100 parts by weight of a crystalline polyester resin (VYLON GM420 manufactured by TOYOBO CO., LTD.) and 1 parts by weight of an o-cresol novolac type epoxy resin (EOCN 4400 manufactured by Nippon Kayaku Co., Ltd.) having at least two glycidyl groups per molecule was used instead. The polyester-based hot-melt adhesive had a melting point of 139° C., a specific gravity of 1.25, and a melt flow index of 29 g/10 minutes.

### Comparative Example 4

A multilayer polishing pad was prepared using the same process as in Example 1, except that a polyester-based hot-melt adhesive containing 100 parts by weight of a crystalline polyester resin (VYLON GM420 manufactured by TOYOBO CO., LTD.) and 18 parts by weight of an o-cresol novolac type epoxy resin (EOCN 4400 manufactured by Nippon Kayaku Co., Ltd.) having at least two glycidyl groups per molecule was used instead. The polyester-based hot-melt adhesive had a melting point of 147° C., a specific gravity of 1.18, and a melt flow index of 15 g/10 minutes.

### Example 9

A multilayer polishing pad was prepared in the same manner as in Example 1, except that the arithmetic average roughness (Ra) of the non-polished surface of the polishing layer was set to 3 μm in Example 1.

### Example 10

A multilayer polishing pad was prepared in the same manner as in Example 1, except that the arithmetic average roughness (Ra) of the non-polished surface of the polishing layer was set to 12 μm in Example 1.

### Example 11

A multilayer polishing pad was prepared in the same manner as in Example 1, except that an adhesive layer including a polyester-based hot-melt adhesive of 50 μm in thickness was used in Example 1.

### Example 12

A multilayer polishing pad was prepared in the same manner as in Example 1, except that an adhesive layer including a polyester-based hot-melt adhesive of 250 μm in thickness was used in Example 1.

TABLE 1

| | | | | | | | Comparative | Comparative |
|---|---|---|---|---|---|---|---|---|
| | Example 1 | Example 2 | Example 3 | Example 4 | Example 5 | Example 6 | Example 1 | Example 2 |
| Amount of | 5 | 5 | 5 | 5 | 5 | 5 | 5 | 5 |
| epoxy resin | | | | | | | | |
| added (part | | | | | | | | |
| by weight) | | | | | | | | |
| Thickness of | 100 | 100 | 100 | 100 | 100 | 100 | 100 | 100 |
| adhesive | | | | | | | | |
| layer (μm) | | | | | | | | |
| Ra of | 5 | 5 | 5 | 5 | 5 | 5 | 5 | 5 |
| non-polished | | | | | | | | |
| surface (μm) | | | | | | | | |
| Area ratio of | 4 | 1.5 | 12.6 | 19.6 | 21.9 | 34.6 | 46.5 | 0.2 |
| holes (%) | | | | | | | | |
| Peeling | Material | Material | Material | Material | Material | Material | Interfacial | Material |
| state | breaking | breaking | breaking | breaking | breaking | breaking | peeling | breaking |
| State of | Good | Good | Good | Good | Good | Good | Occurrence of | Occurrence of |
| polishing | | | | | | | interfacial | breakage on |
| pad | | | | | | | peeling after | cushion layer |
| | | | | | | | 5 hours | |

| | | | Comparative | Comparative | | | | Example |
|---|---|---|---|---|---|---|---|---|
| | Example 7 | Example 8 | Example 3 | Example 4 | Example 9 | Example 10 | Example 11 | 12 |
| Amount of | 2 | 10 | 1 | 18 | 5 | 5 | 5 | 5 |
| epoxy resin | | | | | | | | |
| added (part | | | | | | | | |
| by weight) | | | | | | | | |
| Thickness of | 100 | 100 | 100 | 100 | 100 | 100 | 50 | 250 |
| adhesive | | | | | | | | |
| layer (μm) | | | | | | | | |
| Ra of | 5 | 5 | 5 | 5 | 3 | 12 | 5 | 5 |
| non-polished | | | | | | | | |
| surface (μm) | | | | | | | | |
| Area ratio of | 4 | 4 | 4 | 4 | 4 | 4 | 4 | 4 |
| holes (%) | | | | | | | | |
| Peeling | Material | Material | Interfacial | Interfacial | Material | Material | Material | Material |
| state | breaking | breaking | peeling | peeling | breaking | breaking | breaking | breaking |
| State of | Good | Good | Occurrence | Occurrence | Good | Good | Good | Good |
| polishing | | | of | of | | | | |
| pad | | | interfacial | interfacial | | | | |
| | | | peeling | peeling | | | | |
| | | | after 10 | after 2 | | | | |
| | | | hours | hours | | | | |

### INDUSTRIAL APPLICABILITY

A multilayer polishing pad of the invention is capable of performing planarization materials requiring a high surface planarity such as optical materials including a lens and a reflective mirror, a silicon wafer, a glass substrate or an aluminum substrate for a hard disk and a product of general metal polishing with stability and a high polishing efficiency. A multilayer polishing pad of the invention is preferably employed, especially, in a planarization step of a silicon wafer or a device on which an oxide layer or a metal layer has been formed prior to further stacking an oxide layer or a metal layer thereon.

### DESCRIPTION OF REFERENCE SIGNS

In the drawings, reference numeral 1 represents a multilayer polishing pad, 2 a polishing platen, 3 a polishing agent (slurry), 4 an object to be polished (semiconductor wafer), 5 a support (polishing head), 6 and 7 each a rotating shaft, 8 a polishing layer, 9 a transparent member, 10 and 13 an opening, 11 an adhesive member, 12 a cushion layer, 14 a double-sided adhesive sheet, 15 a through hole.

1. A multilayer polishing pad, comprising a cushion layer, an adhesive member, and a polishing layer placed on the cushion layer with the adhesive member interposed therebetween, wherein the adhesive member is an adhesive layer containing a polyester-based hot-melt adhesive or a double-sided tape comprising a base layer and the adhesive layer provided on each of both sides of the base layer, wherein the adhesive layer or the double-sided tape has a non-adhesive region that occupies 1 to 40% of a surface area of the adhesive layer or the double-sided tape, and the polyester-based hot-melt adhesive contains 100 parts by weight of a polyester resin as a base polymer and 2 to 10 parts by weight of an epoxy resin having two or more glycidyl groups per molecule.

2. The multilayer polishing pad according to claim 1, wherein the polyester resin is a crystalline polyester resin.

3. The multilayer polishing pad according to claim 1, wherein the polishing layer and the cushion layer each have an opening, the multilayer polishing pad further comprising a transparent member placed in the opening of the polishing layer and bonded to the adhesive member.

4. The multilayer polishing pad according to claim 1, wherein the adhesive layer has a thickness of 50 μm to 250 μm.

5. The multilayer polishing pad according to claim 1, wherein the polishing layer has a surface with an arithmetic mean roughness (Ra) of 1 μm to 15 μm on which the adhesive member is placed.

6. A multilayer polishing pad, comprising a polishing layer, an adhesive member, a cushion layer, and a double-sided adhesive sheet stacked in this order, and further comprising a transparent member placed in a hole through the polishing layer, the adhesive member, and the cushion layer and placed on the double-sided adhesive sheet, wherein the adhesive member is an adhesive layer containing a polyester-based hot-melt adhesive or a double-sided tape comprising a base layer and the adhesive layer provided on each of both sides of the base layer, wherein the adhesive layer or the double-sided tape has a non-adhesive region that occupies 1 to 40% of a surface area of the adhesive layer or the double-sided tape, and the polyester-based hot-melt adhesive contains 100 parts by weight of a polyester resin as a base polymer and 2 to 10 parts by weight of an epoxy resin having two or more glycidyl groups per molecule.

7. A method for manufacturing a multilayer polishing pad, comprising the steps of: stacking a polishing layer and a cushion layer with an adhesive member interposed therebetween to form a multilayer polishing sheet; forming a through hole in the multilayer polishing sheet; bonding a double-sided adhesive sheet to the cushion layer of the multilayer polishing sheet having the through hole; and placing a transparent member in the through hole and on the double-sided adhesive sheet, wherein the adhesive member is an adhesive layer containing a polyester-based hot-melt adhesive or a double-sided tape including a base layer and the adhesive layer provided on each of both sides of the base layer, wherein the adhesive layer or the double-sided tape has a non-adhesive region that occupies 1 to 40% of a surface area of the adhesive layer or the double-sided tape, and the polyester-based hot-melt adhesive contains 100 parts by weight of a polyester resin as a base polymer and 2 to 10 parts by weight of an epoxy resin having two or more glycidyl groups per molecule.

8. A method for manufacturing a semiconductor device, comprising the step of polishing a surface of a semiconductor wafer using the multilayer polishing pad according to claim 1.

9. The multilayer polishing pad according to claim 2, wherein the polishing layer and the cushion layer each have an opening, the multilayer polishing pad further comprising a transparent member placed in the opening of the polishing layer and bonded to the adhesive member.

10. The multilayer polishing pad according to claim 2, wherein the adhesive layer has a thickness of 50 μm to 250 μm.

11. The multilayer polishing pad according to claim 2, wherein the polishing layer has a surface with an arithmetic mean roughness (Ra) of 1 μm to 15 μm on which the adhesive member is placed.

12. A method for manufacturing a semiconductor device, comprising the step of polishing a surface of a semiconductor wafer using the multilayer polishing pad according to claim 2.

13. The multilayer polishing pad according to claim 3, wherein the adhesive layer has a thickness of 50 μm to 250 μm.

14. The multilayer polishing pad according to claim 3, wherein the polishing layer has a surface with an arithmetic mean roughness (Ra) of 1 μm to 15 μm on which the adhesive member is placed.

15. A method for manufacturing a semiconductor device, comprising the step of polishing a surface of a semiconductor wafer using the multilayer polishing pad according to claim 3.

16. The multilayer polishing pad according to claim 4, wherein the polishing layer has a surface with an arithmetic mean roughness (Ra) of 1 μm to 15 μm on which the adhesive member is placed.

17. A method for manufacturing a semiconductor device, comprising the step of polishing a surface of a semiconductor wafer using the multilayer polishing pad according to claim 4.

18. A method for manufacturing a semiconductor device, comprising the step of polishing a surface of a semiconductor wafer using the multilayer polishing pad according to claim 5.

19. A method for manufacturing a semiconductor device, comprising the step of polishing a surface of a semiconductor wafer using the multilayer polishing pad according to claim 6.
